(19) United States
(12) Patent Application Publication
(10) Pub. No.: US 2014/0264339 A1
(43) Pub. Date: Sep. 18, 2014

(54) HEAT SLUG HAVING THERMOELECTRIC ELEMENTS AND SEMICONDUCTOR PACKAGE INCLUDING THE SAME

(71) Applicant: Samsung Electronics Co., Ltd., Suwon-si (KR)

(72) Inventors: Ji-Chul Kim, Yongin-si (KR); Hee-Jung Hwang, Suwon-si (KR); Seong-Ho Shin, Hwaseong-si (KR)

(73) Assignee: Samsung Electronics Co., Ltd., Suwon-si (KR)

(21) Appl. No.: 14/132,790

(22) Filed: Dec. 18, 2013

(30) Foreign Application Priority Data
Mar. 15, 2013 (KR) 10-2013-0027884

(51) Int. Cl. F25B 21/02; H01L 23/38; H01L 23/34

(52) U.S. Cl. CPC F25B 21/02; H01L 23/34; H01L 23/345; H01L 23/38
USPC 257/48; 62/3.7

(57) ABSTRACT

In a heat slug and a semiconductor package including the same, the heat slug includes a thermal conductive body having an active face and a dissipating face opposite to the active face, a dielectric layer covering the active face of the body, at least one thermoelectric element arranged on the dielectric layer and a conductive pattern arranged on the dielectric layer and electrically connected to the thermoelectric element. The electrical characteristics of the thermoelectric element are interacted with heat generated from a heat source.

### CROSS-REFERENCE TO RELATED APPLICATIONS

This U.S. non-provisional application claims priority under 35 U.S.C. §119 to Korean Patent Application No. 10-2013-0027884 filed on Mar. 15, 2013 in the Korean Intellectual Property Office, the contents of which are herein incorporated by reference in their entirety.

### BACKGROUND

1. Field

Example embodiments of the present inventive concepts relate to a heat slug and a semiconductor package including the same. More particularly, the example embodiments of the present inventive concepts relate to a heat slug having thermoelectric elements and a semiconductor package including the same.

2. Description of the Related Art

As recent electronic devices have been highly integrated with high performance, semiconductor packages are also manufactured to have small size and high density. Higher performance of the high density semiconductor packages at higher speeds generates a larger amount of heat in the semiconductor package. Thus, sufficient thermal dissipation becomes one of the most important factors for increasing operation stability and product reliability of the semiconductor packages and the electronic systems including the semiconductor packages. Thus, various dissipation systems have been suggested for the high density semiconductor packages.

Recently, a thermal throttling controller has been widely used for automatically reducing a temperature of a semiconductor package. When a high driving power is instantaneously applied to the semiconductor package and, thus, the temperature of the package is instantaneously increased to be higher than a reference temperature, the thermal throttling controller automatically reduces the driving power of a chip or a die on the semiconductor package by using a control program. Thereby, the temperature of the semiconductor package is reduced. Thus, a plurality of temperature sensors are arranged on a circuit board of the semiconductor package for detecting the surface temperature of the die mounted on the circuit board of the semiconductor package. Thus, the surface temperatures of the die are detected by the temperature sensors in real time.

However, due to semiconductor packages being manufactured to have smaller sizes and being manufactured to have high package density, the allowable space for the temperature sensors is gradually reduced. Thus, problems have occurred in which the temperature sensors cannot be positioned at desirable sites in the semiconductor package. Particularly, in a case in which a system on chip (SoC) having a memory interface and a logic interface such as a central process unit (CPU) arranged on a single chip, a number of the temperature sensors and the sites for the temperature sensors are significantly limited due to the reduced inner space of the SoC. As a result, the temperature of the chip is difficult to be accurately detected by the temperature sensors.

In a semiconductor package having the SoC, the operation heat tends to be generated from the logic interface, rather than the memory interface and, thus, the thermal dissipation needs to be performed on the logic interface. However, the temperature sensors are actually arranged on peripheral areas of the logic interface or on the memory interface due to the space limitations of the SoC. As a result, the surface temperature of the logic interface is not accurately detected by the temperature sensors. In addition, the space limitation of the SoC restricts the number of the temperature sensors in the SoC.

### SUMMARY

Example embodiments of the present inventive concepts provide a heat slug having thermoelectric elements for efficiently dissipating heat outwards from a heat source without deteriorating operation efficiency of the heat source.

Example embodiments of the present inventive concepts provide a semiconductor package including the above heat slug.

According to an aspect of the present inventive concepts, there is provided a heat slug including a thermal conductive body having an active face and a dissipating face opposite to the active face, a dielectric layer covering the active face of the thermal conductive body, at least one thermoelectric element arranged on the dielectric layer, and a conductive pattern arranged on the dielectric layer and electrically connected to the thermoelectric element. The electrical characteristics of the thermoelectric element may interact with heat generated from a heat source.

In some embodiments, the thermoelectric element may include a thermistor for detecting a temperature of the heat source.

In some embodiments, the thermoelectric element may include a peltier effect device for forcibly transferring the heat to the thermal conductive body from the heat source by driving currents.

In some embodiments, the thermoelectric element may include a thermistor for detecting a temperature of the heat source and a peltier effect device for forcibly transferring the heat to the thermal conductive body from the heat source by driving currents, so that the thermoelectric element may function as an active thermoelectric heat transfer unit in which the peltier effect device may be selectively operated according to the detected temperature of the heat source by the thermistor.

In some embodiments, the heat slug may further include at least one conductive contact member arranged at a peripheral portion of the thermal conductive body such that the conductive pattern may be connected to an external body having the heat source through the contact member.

In some embodiments, the heat slug may further include a control chip arranged on the dielectric layer and electrically connected with the conductive pattern and the thermoelectric element.

In accordance with another aspect of the present inventive concepts, there is provided a semiconductor package including the above heat slug. The semiconductor package may include a circuit board having an inner electrical circuit pattern therein, a semiconductor chip mounted on the circuit board and electrically connected with the inner circuit pattern of the circuit board, an encapsulant arranged on the circuit board and encapsulating the semiconductor chip, thereby protecting the semiconductor chip from surroundings, and a heat slug positioned on the encapsulant and dissipating a heat generated from the semiconductor chip outwards. The heat slug may include a thermal conductive body having an active face and a dissipating face opposite to the active face, a dielectric layer covering the active face of the thermal conductive body, at least one thermoelectric element arranged on the dielectric layer having electrical characteristics interacting with the heat generated from the semiconductor chip and a conductive pattern arranged on the dielectric layer and electrically connected to the thermoelectric element.

In some embodiments, the heat slug may further include at least one conductive contact member arranged at a peripheral portion of the thermal conductive body such that the conductive pattern may be connected to an external body having the heat source through the contact member.

In some embodiments, the thermoelectric element may include at least one of a thermistor for detecting a temperature of the heat source and a peltier effect device for forcibly transferring the heat to the thermal conductive body from the heat source by driving currents.

In some embodiments, the semiconductor chip may include a control unit electrically connected to the thermoelectric element via the inner circuit pattern and the conductive contact member.

In some embodiments, a reference temperature of the semiconductor chip may be stored in the control unit and the control unit may generate a control signal for driving the peltier effect device when a detected temperature of the semiconductor chip may be higher than the reference temperature of the semiconductor chip.

In some embodiments, the heat slug may further include a control chip arranged on the dielectric layer and electrically connected with the conductive pattern and the thermoelectric element.

In some embodiments, a reference temperature of the semiconductor chip may be stored in the control chip and the control chip may generate a control signal for driving the peltier effect device when a detected temperature of the semiconductor chip may be higher than the reference temperature of the semiconductor chip.

In some embodiments, the thermoelectric element may include a thermistor for detecting a temperature of the heat source and a peltier effect device for forcibly transferring the heat to the thermal conductive body from the heat source by driving currents, and the heat slug may further include a control chip electrically connected with the conductive pattern and the thermoelectric element and in which a reference temperature of the semiconductor chip may be stored, so that the control chip may generate a control signal for driving the peltier effect device when the detected temperature of the semiconductor chip by the thermistor may be higher than the reference temperature of the semiconductor chip.

In some embodiments, a plurality of the thermoelectric elements may be provided in the heat slug in such a configuration that the thermoelectric elements may be arranged to correspond to local sites of the semiconductor chip, respectively, and the electrical characteristics of each of the thermoelectric elements may be interacted with a heat generated from the corresponding local site independently from a rest of the local sites.

In accordance with another aspect of the present inventive concepts, there is provided a semiconductor package which includes a semiconductor chip having at least one heat source and a heat slug. The heat slug includes a thermal conductive body having an active face and a dissipating face opposite to the active face, a dielectric layer covering the active face of the thermal conductive body, and at least one thermoelectric element in contact with the at least one heat source. The at least one thermoelectric element detects a temperature of the heat source and dissipates heat to the thermal conductive body.

In some embodiments, the at least one thermoelectric element includes a thermistor for detecting a temperature of the heat source.

In some embodiments, the at least one thermoelectric element includes a peltier effect device for forcibly transferring the heat to the thermal conductive body from the heat source by driving currents.

In some embodiments, the thermoelectric element includes a thermistor for detecting a temperature of the heat source and a peltier effect device for forcibly transferring the heat to the thermal conductive body from the heat source by driving currents, so that the thermoelectric element functions as an active thermoelectric heat transfer unit in which the peltier effect device is selectively operated according to the detected temperature of the heat source by the thermistor.

In some embodiments, the at least one heat source comprises a plurality of heat sources and the at least one thermoelectric element comprises a plurality of thermoelectric elements, and wherein the plurality of thermoelectric elements contact the plurality of heat sources, respectively.

According to example embodiments of the present inventive concepts, at least one of a temperature detector, such as a thermistor, and a heat transfer unit, such as a peltier device, may be arranged on the heat slug in such a configuration that the temperature detector and the heat transfer unit may be positioned on or over the heat sources of the semiconductor chip. Thus, a forcible heat dissipation may be performed on some of the heat sources when the temperature of the heat sources is higher than the reference temperature by the thermoelectric elements of the heat slug. Thus, the cut off of the driving power to the semiconductor chip may be minimized even though some of the heat sources are temporarily under a high temperature which is over the reference temperature. Accordingly, the operation efficiency of the semiconductor chip having the plurality of heat sources may be sufficiently improved by the heat slug having the thermoelectric elements. In addition, the dissipation mode of the heat slug may be automatically changed between the active mode and the passive mode according to the temperature of the heat sources and the heat dissipation may be individually performed on each of the heat sources independently from one another. When the temperature of the heat source is lower than the reference temperature, the heat slug may transfer the heat outwards from the normal heat source in the passive mode. In contrast, when the temperature of the heat source is increased to be higher than the reference temperature due to an instantaneous excessive operation, the heat slug may forcibly transfer the heat outwards from the excessively operated heat source in the active mode by using the heat transfer unit, such as, for example, the peltier device.

In an embodiment having the SoC structure in which a plurality of functional unit chips may be arranged in a single die and the amount of heat from each unit chip may be different from one another, the temperature detector and the heat transfer unit may be sufficiently provided at each unit chip without the space margin limitation, since the temperature detector and the heat transfer unit may be provided on the heat slug rather than on the unit chip of the SoC. Thereby, the efficiency of the heat dissipation of the SoC is improved. Thus, although the semiconductor package may be downsized and the number of the functional unit chips may increase in the semiconductor chip, the heat may be sufficiently dissipated from each of the unit chips through the active cooling process or the passive cooling process of the heat slug.

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIG. 1A is a cross-sectional view illustrating a heat slug in accordance with an example embodiment of the present inventive concepts.

FIG. 1B is cross-sectional view illustrating another heat slug in accordance with an example embodiment of the present inventive concepts.

FIG. 2A is a cross-sectional view illustrating a heat slug in accordance with another example embodiment of the present inventive concepts.

FIG. 2B is cross-sectional view illustrating another heat slug in accordance with an example embodiment of the present inventive concepts.

FIG. 3A is a cross-sectional view illustrating a heat slug in accordance with another example embodiment of the present inventive concepts.

FIG. 3B is cross-sectional view illustrating another heat slug in accordance with an example embodiment of the present inventive concepts.

FIGS. 4A to 4F are cross-sectional views illustrating a method of forming the heat slug illustrated in FIG. 1A in accordance with an example embodiment of the present inventive concepts.

FIG. 5A is a cross-sectional view illustrating a semiconductor package including the heat slug illustrated in FIG. 3A in accordance with an example embodiment of the present inventive concepts.

FIG. 5B is a plan view illustrating the semiconductor package in FIG. 5A in accordance with an example embodiment of the present inventive concepts.

FIG. 6 is a cross-sectional view illustrating a semiconductor package including the heat slug shown in FIG. 3A in accordance with another example embodiment of the present inventive concepts.

### DETAILED DESCRIPTION OF THE EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Hereinafter, example embodiments of the present inventive concepts will be explained in detail with reference to the accompanying drawings.

Heat Slug

FIG. 1A is a cross-sectional view illustrating a heat slug 900 in accordance with an example embodiment of the present inventive concepts.

Referring to FIG. 1A, the heat slug 900 in accordance with the example embodiment of the present inventive concepts may include a body 100 comprising thermal conductive materials and having an active face 101 and a dissipating face 102, a dielectric layer 200 covering the active face 101, a thermoelectric element 300 arranged on the dielectric layer 200, a conductive pattern 400 arranged on the dielectric layer 200 an a plurality of contact members 500. The electrical characteristics of the thermoelectric element 300 may interact with heat generated from a heat source HS. The conductive pattern 400 may be electrically connected to the thermoelectric element 300.

In some embodiments, the body 100 may maintain the shape of the heat slug 900 and may function as a heat transfer path for dissipating heat from the heat source HS outwards. Thus, the body 100 may comprise a material having good thermal conductivity and sufficient rigidity. For example, the body 100 may include aluminum (Al) having excellent thermal conductivity and good shape forming characteristics. The heat source HS may include an external body E to which the heat slug 900 may be coupled. Particularly, the heat soured HS may include a local area of the external body E at which a relatively larger amount of heat may be generated compared with other areas of the external body E.

The body 100 may have a sufficient thickness in relation to a whole thickness of the external body E and may provide an efficient dissipation of the heat generated from the heat source HS. The active face 101 of the body 100 may face the heat source HS and the dissipating face 102 may face environmental surroundings of the heat slug 900. Thus, the heat generated from the heat source HS may dissipate to the environmental surroundings through the dissipating face 102. That is, the heat generated from the heat source HS may be transferred to the body 100 through the active face 101 of the body 100 and may be dissipated outwards through the dissipating face 102 of the body 100.

The dielectric layer 200 may cover the active face 101. The thermoelectric element 300 and the conductive pattern 400 may be electrically insulated from the body 100 by the dielectric layer 200. Various material layers may be used for the dielectric layer 200 as long as the thermoelectric element 300 and the conductive pattern 400 are sufficiently insulated from the body 100, that is, electrically insulated, by the dielectric layer 200. In the present example embodiment, the dielectric layer 200 may include an epoxy resin.

The thermoelectric element 300 and the conductive pattern 400 may be arranged on the dielectric layer 200. The thermoelectric element 300 may detect the temperature of the heat source HS by using the interaction of heat and electricity and may perform a heat transfer from the heat source HS to the body 100. For example, the thermoelectric elements 300 may include a temperature detector element for detecting the temperature of the heat source HS and a heat transfer element for performing a heat transfer between the body 100 and the heat source HS by driving currents.

In the present example embodiment, the thermoelectric element may include a temperature detector element such as a thermistor 310 for detecting the temperature of the heat source HS. However, any other temperature detectors may be used as the temperature detector of the thermoelectric element 300 as long as the temperature of the heat source HS can be detected by using the interaction between heat and electricity.

The thermistor 310 may include a contact portion 311 in contact with the heat source HS and a transmit portion 312. The transmit portion 312 detects the temperature of the heat source HS and transmits the detected temperature to the conductive pattern 400. The electrical resistance of the contact portion 311 may be varied according to the temperature of the heat source HS and the transmitting portion 312 may detect and transmit the temperature of the heat source HS based on the variation of the electrical currents due to the resistance variation of the contact portion 311. In the present example embodiment, the contact portion 311 may include sintered compounds of one of an oxide, a carbonate, an acetate and a chloride having any one material selected from the group consisting of iron (Fe), nickel (Ni), manganese (Mn), molybdenum (Mo), copper (Cu) and combinations thereof. The transmitting portion 312 may include a control unit for converting the current variation of the contact portion 311 to the corresponding temperature.

When the amount of the heat from the heat source HS is varied, the electrical resistance of the contact portion 311 may be varied according to the heat variation in real time. Thus, the temperature of the heat source HS may be detected in real time by the transmitting portion 312.

The conductive pattern 400 may be arranged on the dielectric layer 200 and may be electrically connected to the thermistor 310. In the present example embodiment, the conductive pattern 400 may include metals having high electrical conductivity. Examples of the metals may include any one of copper (Cu), aluminum (Al), tungsten (W) and combinations thereof.

In some embodiments, the thermistor 310 and the conductive pattern 400 may be electrically connected by a bonding wire 410. In some embodiments, the thermistor 310 may be arranged on the conductive pattern 400 and electrically connected with the conductive pattern 400 by a solder ball and a penetration electrode. The thermistor 310 may be positioned corresponding to the heat source HS in such a way that the thermistor 310 may be interposed between the heat slug 900 and the external body E. That is, the thermistor 310 may be positioned such that the thermistor 310 is interposed between the body 100 of the heat slug 900 and the external body E. In the present example embodiment, the combination of the heat slug 900 and the external body E may allow the thermistor 310 to be positioned on the heat source HS.

Particularly, the thermistor 310 may be provided with every heat source HS of the device. In such an embodiment, a number of the thermistors 310 may be positioned on a number of the heat sources HS, respectively. Therefore, the temperatures of each heat source HS may be individually and independently detected.

A plurality of contact members 500 may be arranged along a peripheral portion of the body 100 and may be interposed between the conductive pattern 400 and the external body E having the heat source HS. Thus, the conductive pattern 400 may be connected to the external body E via the contact member 500. Therefore, the detected temperature of the heat source HS may be transferred to the conductive pattern 400 from the thermistor 310 and, then, transferred to the external body E via the contact member 500. For example, the contact member 500 may include solder ball arrays.

The detected temperature of the heat source HS may be compared with a preset reference temperature in a control unit (not shown) of the external body E. The reference temperature may include a maximal allowable temperature of the heat source HS and may be preset in the external body E in advance.

When the detected temperature is higher than the reference temperature, the control unit generates a control signal to reduce the temperature of the heat source HS. For example, a thermal throttling controller (not shown) may be provided with the control unit. The thermal throttling controller may temporarily stop or reduce the operation of the heat source HS. Thus, a smaller amount of the heat may be generated from the heat source HS and the temperature of the heat source HS may be reduced such that it is below the reference temperature.

FIG. 1B is cross-sectional view illustrating an alternative embodiment of the heat slug 900 illustrated in connection with FIG. 1A. A heat slug 900a of FIG. 1B may have substantially the same structures as the heat slug 900 illustrated in FIG. 1A, except for a control chip 600 that communicates with the thermistor 310. Thus, in FIG. 1B, the same reference numerals in FIG. 1B as in FIG. 1A denote the same elements, and any further detailed descriptions on the same elements will be omitted hereinafter.

Referring to FIG. 1B, the heat slug 900a may include the control chip 600 that may be arranged on the dielectric layer 200 and may be connected with the conductive pattern 400 and the thermistor 310. In the present example embodiment, the thermistor 310, the control chip 600 and the conductive pattern 400 are electrically connected in series by the bonding wires 410.

The detected temperature of the heat source HS may be transferred to the control chip 600 by the transmitting portion 312 of the thermistor 310. The reference temperature of the heat source HS may be preset in the control chip 600. A reference temperature may include the maximal allowable temperature of the heat source HS and may be varied according to the external body E that is coupled with the heat slug 900a.

When the detected temperature of the heat source HS is higher than the reference temperature, the control chip 600 may generate a control signal for reducing the temperature of the heat source HS. The control signal may be transferred to the conductive pattern 400 by the control chip 600 by the bonding wire 410 and then may be transferred to the external body E by the conductive pattern 400 through the contact member 500. The operation of the heat source HS may be reduced or stopped according to the control signal, thereby reducing the operation heat of the heat source HS.

FIG. 2A is a cross-sectional view illustrating a heat slug 901 in accordance with an example embodiment of the present inventive concepts. The heat slug 901 in FIG. 2A may have substantially the same structures as the heat slug in FIG. 1A, except that a Peltier effect device 320 may be provided in place of the thermistor 310 as the thermoelectric element. Thus, in FIG. 2A, the same reference numerals in FIG. 2B as in FIG. 2A denote the same elements, and any further detailed descriptions on the same elements will be omitted.

Referring to FIG. 2A, the heat slug 901 in accordance with another example embodiment of the present inventive concepts may include a peltier effect device 320 that transfers the operation heat of the heat source HS to the body 100 by driving currents. The driving currents may be applied to the peltier device 320 by the conductive pattern 400 and, thus, the heat generated from the heat source HS may be forced to be transferred to the body 100. The peltier effect device 320 is arranged on the dielectric layer 200 such that the peltier effect device 320 is between the dielectric layer 200 and the heat source HS.

The peltier device 320 may include a first heat transfer unit 321 arranged on the heat source HS, a second heat transfer unit 322 arranged on the dielectric layer 200 and a driving unit 323 interposed between the first and the second heat transfer units 321 and 322. An insulation layer 321a may be interposed between the first heat transfer unit 321 and the heat source HS of the external device E. The driving unit 323 may include a semiconductor device in which two kinds of semiconductors having different electrical polarity may make contact with each other.

When the driving currents are applied to the driving unit 323, the first heat transfer unit 321 may absorb the heat from the heat source HS and the second heat transfer unit 322 may transfer the heat to the body 100 from the first heat transfer unit 321. Thus, the operation heat generated from the heat source HS may be transferred to the body 100 by the peltier device 320 and finally be dissipated outwards from the body 100. For example, the peltier device 320 may include a P-N junction structure having compounds of bismuth (Bs) and tellurium (Te) such as Bi3Te2. The peltier device 320 on the dielectric layer 200 may be electrically connected to the conductive pattern 400 by the bonding wire 410.

The driving current for driving the peltier device 320 may be applied by the conductive pattern 400. For example, a temperature detection circuit (not shown) may be provided in the external body E and the temperature of the heat source HS may be detected by the temperature detection circuit. Then, the detected temperature of the heat source HS may be transferred to the control unit (not shown) in the external body E and may be compared with the preset reference temperature. The reference temperature may include a maximal allowable temperature of the heat source HS that may be preset in the external body E in advance.

When the detected temperature of the heat source HS is higher than the reference temperature, the control unit in the external device E may generate a control signal to drive the peltier device 320. According to the control signal, the driving currents may be applied to the driving unit 323 by the conductive pattern 400 and, thus, the operation heat of the heat source HS may be transferred to the body 100 by the peltier device 320. Thereby, the temperature of the heat source HS may be decreased to be below the reference temperature. Therefore, a pair of the temperature detection circuit built in the external body E and the peltier device 320 may function as an active cooling device for automatically and actively cooling the heat source HS below the reference temperature every time the detected temperature of the heat source HS is higher than the reference temperature.

The peltier device 320 may be positioned corresponding to the heat source HS in such a way that the peltier device 320 may be interposed between the body 100 of the heat slug 901 and the external body E. In the present example embodiment, the combination of the heat slug 901 and the external body E may allow the peltier device 320 to be positioned on the heat source HS. Particularly, the peltier device 320 may be provided with every heat source HS of the device. In such a case, a plurality of peltier devices 320 may be positioned on a plurality of the heat sources HS, respectively. Thus, the temperatures of each heat source HS may be individually and independently detected. Therefore, the active cooling process may be individually performed on each of the heat sources HS independently from one another.

FIG. 2B is cross-sectional view illustrating a modification alternative embodiment of the heat slug 901 illustrated in connection with FIG. 2A. A heat slug 901a of FIG. 2B may have substantially the same structures as the heat slug 901 illustrated in FIG. 2A, except for a control chip 600 that communicates with the peltier device 320. Thus, in FIG. 2B, the same reference numerals in FIG. 2B as in FIG. 2A denote the same elements, and any further detailed descriptions on the same elements will be omitted hereinafter.

Referring to FIG. 2B, the heat slug 901a may include the control chip 600 that may be arranged on the dielectric layer 200 and may be connected with the conductive pattern 400 and the peltier device 320. In the present example embodiment, the peltier device 320, the control chip 600 and the conductive pattern 400 are electrically connected in series by the bonding wires 410.

The temperature of the heat source HS may be detected by the temperature detection circuit in the external body E and the detected temperature of the heat source HS may be transferred to the conductive pattern 400 and, then, transferred to the control chip 600 by the conductive pattern 400. A reference temperature of the heat source HS may be preset in the control chip 600. The reference temperature may include the maximal allowable temperature of the heat source HS and be varied according to the external body E that may be combined with the second modified heat slug 901a.

When the detected temperature of the heat source HS is higher than the reference temperature in the control chip 600, the control chip 600 may generate a control signal for driving the peltier device 320. The control signal may be transferred to the peltier device 320 through the bonding wire 410. Then, the peltier device 320 may be operated to transfer the heat to the body 100 of the heat slug 901a from the heat source HS, thereby reducing the temperature of the heat source HS under the reference temperature.

FIG. 3A is a cross-sectional view illustrating a heat slug in accordance with another example embodiment of the present inventive concepts. The heat slug 902 in FIG. 3A may have substantially the same structures as the heat slugs described in connection with FIG. 1A or FIG. 2A, except that both of the thermistor 310 in FIG. 1A and the Peltier device 320 in FIG. 2A may be installed as the thermoelectric element. Thus, in FIG. 3A, the same reference numerals in FIG. 3A as in FIGS. 1A and 2A denote the same elements, and any further detailed descriptions on the same elements will be omitted.

Referring to FIG. 3A, the heat slug 902 in accordance with another example embodiment of the present inventive concepts may include both of the thermistor 310 and the peltier effect device as the thermoelectric element. The thermistor 310 may make contact with the heat source HS and may detect the temperature of the heat source HS. The peltier effect device 320 may transfer the operation heat of the heat source HS to the body 100 by driving currents. Accordingly, the thermoelectric element 300 in the present example embodiment may function as an active thermoelectric heat transfer member in which the peltier device 320 may be selectively operated according to the detected temperature of the heat source HS detected by the thermistor 310, thereby automatically and forcibly reducing the temperature of the heat source HS under a reference temperature when the detected temperature is higher than the reference temperature in real time.

As described above, the driving currents for driving the peltier effect device 320 may be selectively applied to the driving unit 323 of the peltier effect device 320, as illustrated in FIGS. 2A and 2B, according to the detected temperature of the heat source HS by the thermistor 310. The temperature of the heat source HS may be detected by the thermistor 310 in real time, and the detected temperature of the heat source HS may be immediately transferred from the thermistor 310 to a control unit (not shown) in the external body E substantially in real time through the conductive pattern 400 and the contact member 500. The detected temperature may be compared with the reference temperature in the control unit in the external body E. When the detected temperature is higher than the reference temperature, the control unit in the external body E may generate a control signal for driving the peltier device 320. According to the control signal, the driving currents may be applied to the driving unit 323 of the peltier device 320 through the conductive pattern 400 and the contact member 500 and the heat transfer from the heat source HS to the body 100 may be performed by the peltier device 320, thereby reducing the temperature of the heat source HS under the reference temperature.

Accordingly, the thermistor 310 and the peltier device 320 may function as the active heat transfer device in which the heat of the heat source HS may be forcibly or actively dissipated outwards from the heat slug 902 when the temperature of the heat source HS is higher than the preset reference temperature. Particularly, although the heat source HS may instantaneously generate an excessive amount of heat to an instantaneous high temperature due to a momentary high power to the heat source HS, the high temperature of the heat source HS may be instantaneously reduced in real time, since the temperature of the heat source HS is detected in real time.

The thermistor 310 and the peltier effect device 320 may be positioned corresponding to the heat source HS in such a way that the thermistor 310 and the peltier device 320 may be interposed between the body 100 of the heat slug 902 and the external body E. In the present example embodiment, the combination of the heat slug 902 and the external body E may allow the thermistor 310 and the peltier effect device 320 to be positioned on the heat source HS. Particularly, the thermistor 310 and the peltier effect device 320 may be provided with every heat source HS of the device.

In such an embodiment, a plurality of the thermistors 310 and the peltier effect devices 320 may be positioned on a plurality of the heat sources HS, respectively. Thus, the temperatures of each heat source HS may be individually and independently detected. Therefore, the active cooling process may be individually and independently performed on each of the heat sources HS.

In a another example embodiment, the thermistor 310 and the peltier effect device 320 may be further selectively positioned on a local site of the external body E at which the heat may be intensively dissipated from the external body E and, thus, of which the temperature may be locally higher than a reference temperature. That is, an active cooling may be performed on a local area of the external body E.

FIG. 3B is cross-sectional view illustrating an alternative embodiment of the heat slug 902 illustrated in connection with FIG. 3A. A heat slug 902a of FIG. 3B may have substantially the same structures as the heat slug 902 illustrated in FIG. 3A, except for a control chip 600 that communicates with the thermistor 310 and the peltier effect device 320. Thus, in FIG. 3B, the same reference numerals in FIG. 3B as in FIG. 3A denote the same elements, and any further detailed descriptions on the same elements will be omitted hereinafter.

Referring to FIG. 3B, the heat slug 902a may include a control chip 600 that may be arranged on the dielectric layer 200 and may be connected with the conductive pattern 400 and the peltier device 320. In the present example embodiment, the peltier device 320, the control chip 600 and the conductive pattern 400 are electrically connected in series by the bonding wires 410. The control chip 600 may have substantially the same structures as the control chip of the first and the second modified heat slugs 900a and 901a of FIGS. 1B and 2B, respectively.

The temperature of the heat source HS may be detected by the thermistor 310 and the detected temperature of the heat source HS may be transferred to the control chip 600 by the conductive pattern 400. A reference temperature of the heat source HS may be preset in the control chip 600. The reference temperature may include the maximal allowable temperature of the heat source HS and be varied according to the external body E that may be combined with the heat slug 902a.

The peltier effect device 320 may transfer the operation heat of the heat source HS to the body 100 by driving currents. Accordingly, the thermoelectric element 300 in the present example embodiment may function as an active thermoelectric heat transfer member in which the peltier device 320 may be selectively operated according to the detected temperature of the heat source HS detected by the thermistor 310, thereby automatically and forcibly reducing the temperature of the heat source HS under a reference temperature when the detected temperature is higher than the reference temperature in real time. The peltier effect device 320 may transfer the operation heat of the heat source HS to the body 100 by driving currents. Accordingly, the thermoelectric element 300 in the present example embodiment may function as an active thermoelectric heat transfer member in which the peltier device 320 may be selectively operated according to the detected temperature of the heat source HS detected by the thermistor 310, thereby automatically and forcibly reducing the temperature of the heat source HS under a reference temperature when the detected temperature is higher than the reference temperature in real time.

Particularly, the driving currents for driving the peltier device 320 may be selectively applied to the driving unit 323 according to the temperature of the heat source HS detected by the thermistor 310. The temperature of the heat source HS may be detected by the thermistor 310 and the detected temperature may be transferred from the thermistor 310 to the control chip 600 that may be electrically connected to both of the thermistor 310 and the peltier effect device 320. The detected temperature may be compared with the reference temperature that may be preset in the control chip 600 in advance. When the detected temperature is higher than the reference temperature, a dissipation signal may be generated in the control chip 600 and the dissipation signal may be transferred from the control chip 600 to the peltier device 320. According to the dissipation signal, the peltier effect device 320 may be operated to transfer the heat to the body 100 of the heat slug 902a from the heat source HS. Then, the heat may be dissipated to the surroundings such as an atmosphere from the body 100 through heat conduction.

Accordingly, the thermistor 310 and the peltier effect device 320 may function as an active heat transfer device in which the heat of the heat source HS may be dissipated outwards by the heat slug 902a only when the temperature of the heat source HS is higher than the preset reference temperature.

Accordingly, when the detected temperature of the heat source HS is higher than the reference temperature in the control chip 600, the control chip 600 may generate a control signal for driving the peltier device 320. The control signal may be transferred to the peltier device 320 through the bonding wire 410. Then, the peltier device 320 may be operated to transfer the heat to the body 100 from the heat source HS, thereby reducing the temperature of the heat source HS under the reference temperature.

In addition, when all of the thermistor 310, the peltier device 320 and the control chip 600 are positioned on the dielectric layer 200 of the heat slug 902a, the contact member 500 for combining the heat slug 902a to the external body E may not necessarily need conductive materials, thereby simplifying the configurations of the heat slug 902a.

While the thermistor 310 may be disclosed as detecting the temperature of the heat source HS and the peltier device 320 may be disclosed as selectively conducting the heat transfer, any other thermoelectric elements may also be used in place of the thermistor 310 and the peltier device 320 as long as the temperature of the heat source may be sufficiently detected and the heat transfer may be selectively conducted according to the detected temperature of the heat source HS.

According to example embodiments of the heat slug, at least one of the thermistor 310 for detecting the temperature of the heat source and the peltier effect device 320 for selectively conducting the heat transfer according to the detected temperature of the heat source may be in contact with the heat source. Thus, the heat may be automatically dissipated outwards only when the temperature of the heat source is higher than the reference temperature in real-time. Therefore, the dissipation mode of the heat slug may be automatically converted according to the temperature of the heat source. That is, when the temperature of the heat source is below the reference temperature, the heat slug may be operated in a passive mode. However, when the temperature of the heat source is over the reference temperature, the heat slug may be operated in an active mode such that the heat of the heat source may be actively or forcibly dissipated outwards by using the thermistor 310 and/or the peltier effect device 320. Thus, the heat slug may be operated in a passive mode or in an active mode according to the temperature of the heat source.

FIGS. 4A to 4F are cross-sectional views illustrating a method of forming the heat slug illustrated in FIG. 1A in accordance with example embodiment of the present inventive concepts.

Referring to FIG. 4A, a conductive metal plate 100a may be prepared for the body 100 and a resin coated copper (RCC) 250a may be prepared independently from the conductive metal plate 100a. For example, a conductive metal bulk may be formed into the metal plate 100a having a desired thickness by a metal forming process. A mixture of resin, solvent and chemicals may be formed into a preliminary resin layer 200a and a copper (Cu) layer 400a may be formed on the preliminary resin layer 200a, thereby preparing the RCC 250a. The copper layer 400a may be formed on the preliminary resin layer 200a by a deposition process. Otherwise, the copper layer 400a may be stacked on the preliminary resin layer 200a and a molding process may be conducted under a high pressure and a high temperature.

Referring FIG. 4B, the RCC 250a may be adhered to the metal plate 100a. An adhesive (not shown) may be interposed between the RCC 250a and the metal plate 100a for the adhesion of the adhesion of the RCC 250a and the metal plate 100a. Otherwise, the RCC 250a and the metal plate 100a may be pressed under a high pressure.

Referring to FIG. 4C, a mask pattern (not shown) may be formed on the copper layer 400a and the copper layer 400a may be formed into a copper pattern 400 by an etching process using the mask pattern as an etching mask. That is, the copper pattern may be formed on the preliminary resin layer 200a as the conductive pattern 400 of the heat slug 900. Thus, the preliminary resin layer 200a may be partially exposed through the copper pattern 400. The partially exposed preliminary resin layer 200a may function as the dielectric layer 200 and the metal plate 100a under the preliminary resin layer 200a may function as the body 100. A surface of the metal plate 100a that may be covered with the preliminary resin layer 200a may be defined as the active face 101 of the body 100. As a result, the active face 101 of the body 100 may be covered with the dielectric layer 200 and the copper pattern 400 may be formed on the dielectric layer 200.

The copper pattern 400 may be formed on the dielectric layer in such a configuration that the dielectric layer 200 over the heat source HS may be exposed through the copper pattern 400. In a subsequent process, the thermoelectric element 300 may be formed on the dielectric layer 200 over the heat source HS, as illustrated in FIG. 4D and FIG. 1A. Thus, the copper pattern 400 may be shaped into such a configuration that the thermoelectric element 300 may be sufficiently positioned over the heat source HS.

Referring to FIG. 4D, the thermoelectric element 300 may be formed on the dielectric layer 200 exposed through the copper pattern 400. The copper pattern 400 and the thermoelectric element 300 may be electrically connected to each other by the bonding wire 410. The thermoelectric element 300 may be arranged on the dielectric layer 200 in various configurations according to the characteristics of the thermoelectric element 300. The thermoelectric element 300 may also be formed on the copper pattern 400 without the bonding wire 410. Further, the control chip 600 shown in FIG. 1B may be selectively formed on the dielectric layer 200.

Referring to FIG. 4E, after forming the thermoelectric element 300 on the dielectric layer 200, the body 100 may be molded according to the shape of the heat source HS that may be combined with heat slug 900. For example, the thermoelectric element 300 may be arranged at a central portion of the body 100 and the peripheral portion of the body 100 may be bent such that the thermoelectric element 300 may be recessed or concaved and the copper pattern 400 may be protruded from the thermoelectric element 300 at the peripheral portion of the body 100.

Referring to FIG. 4F, the conductive contact member 500 may be selectively formed on the copper pattern 400 at the peripheral portion of the body 100. The contact member 500 may mechanically couple the heat slug 900 to the external body E including the heat source HS. Further, the heat slug 900 may be electrically connected to the external body E including the heat source HS by the contact member 500. For example, the contact member 500 may include solder ball arrays.

According to the method of forming the heat slug, the RCC layer may be formed into the RCC pattern by an etching process and the thermoelectric element may be formed on the RCC pattern, thereby forming the heat slug for performing the active cooling.

Semiconductor Package Including the Heat Slug

FIG. 5A is a cross-sectional view illustrating a semiconductor package including the heat slug 902 illustrated in FIG. 3A in accordance with an example embodiment of the present inventive concepts. FIG. 5B is a plan view illustrating the semiconductor package in FIG. 5A in accordance with an example embodiment of the present inventive concepts.

Referring to FIGS. 5A and 5B, the semiconductor package 1900 in accordance with an example embodiment of the present inventive concepts may include a circuit board 1100 having an inner electrical circuit pattern 1120 therein, and a semiconductor chip 1200 mounted on the circuit board 1100 and electrically connected with the inner circuit pattern 1120 of the circuit board 1100. The semiconductor package 1900 may include an encapsulant 1300 arranged on the circuit board 1100 encapsulating the semiconductor chip 1200 such that the semiconductor chip 1200 may be protected from external surroundings and may be stably fixed to the circuit board 1100 and a heat slug 1000 positioned on the encapsulant 1300 and dissipating the heat generated from the semiconductor chip 1200 outwards to the surroundings. The heat slug 1000 may include a body 100 comprising thermal conductive materials and having an active face 101 and a dissipating face 102, a dielectric layer 200 covering the active face 101, a thermoelectric element 300 arranged on the dielectric layer 200 and a conductive pattern 400 arranged on the dielectric layer 200 and electrically connected to the thermoelectric element 300. The thermoelectric element 300 having electrical characteristics which interact with heat generated from the semiconductor chip 1200.

In an example embodiment, the circuit board 1100 may be shaped into a plate having a sufficient rigidity and may include the inner circuit pattern 1120 therein. For example, the circuit board 1100 may include a board body 1110 shaped into a plate with the rigidity and comprising insulating and heat-resistive materials. The inner circuit pattern 1120 may be arranged inside the board body 1110. The inner circuit pattern 1120 may include a plurality of conductive lines and may be connected to a plurality of contact pads (not shown) arranged on upper and lower faces of the board body 1110. A contact terminal 1130 may be arranged on the contact pad at a bottom of the circuit board 1100 and an external system (not shown) may make contact with the contact terminal 1130. The semiconductor chip 1200 may make contact with the contact pads on the upper face of the body 1110. Thus, the semiconductor chip 1200 and the external system may be electrically connected to each other through the inner circuit pattern 1120 and the contact terminal 1130. For example, the contact terminal 1130 may include a solder ball.

For example, the body 1110 may include a thermosetting plastic plate such as an epoxy resin plate and a polyimide plate. Otherwise, the body 1110 may include a plate on which a heat-resistive organic film such as a liquid crystal polyester film and a polyamide film may be coated. The inner circuit pattern 1120 may include a plurality of conductive lines or wirings that may be electrically connected with the semiconductor chip 1200 and the external system. The inner circuit pattern 1120 may include a power line for applying an electric power, a plurality of signal lines for communicating data signals with the semiconductor chip 1200 and a ground line for electrically grounding the signal lines and the power line. The conductive lines or the wirings of the circuit pattern 1120 may be electrically insulated from one another by a plurality of insulation interlayers (not shown). In the present example embodiment, the circuit board 1100 may include a printed circuit board (PCB) in which the inner circuit pattern 1120 may be formed by a printing process.

The semiconductor chip 1200 may include an active device such as an integrated circuit device mounted on the circuit board 1100. Thus, when a driving power is applied to the semiconductor chip 1200, an electrical operation such as an electrical amplification and an electrical oscillation may be conducted and, as a result, driving heat may be generated from the semiconductor chip 1200.

For example, the semiconductor chip 1200 may include a plurality of conductive structures (not illustrated) stacked on a semiconductor substrate such as a silicon wafer using a plurality of insulation interlayers and a plurality of wiring structures separated from the conductive structures by the insulation interlayers for transferring signals to the conductive structures. The conductive structures and the wiring structures may be protected from surroundings by a passivation layer.

The conductive structure may include, for example, a unit structure of a dynamic random access memory (DRAM) device having a transistor and a capacitor corresponding to each other. In some embodiments, the conductive structure may include, for example, a unit transistor of an operation block of a flash memory device having string transistors, cell transistors and ground transistors. The conductive structure may include, for example, at least one logic device for operating the DRAM device and the flash memory device.

The wiring structure may include a metal plug penetrating through the insulation interlayer and making contact with the conductive structure and a metal wiring extending on the insulation interlayer and connected to the metal plug. The metal wiring may include a signal line for transferring input/output signals to the conductive structure, a power line for applying an electric power to the conductive structure and a ground line for electrically grounding the conductive structure.

The semiconductor chip 1200 may include, for example, a flip chip structure in which an active face of the semiconductor chip 1200 may face down toward an upper surface of the circuit board 1100. Thus, interconnectors 1210 such as, for example, solder bumps may be interposed between electrode pads (not shown) of the semiconductor chip 1200 and the contact pads of the circuit board 1100. Thus, the semiconductor chip 1200 may be electrically connected to the circuit board 1100 via the interconnectors 1210. The interconnectors 1210 may be bonded to the circuit board 1100 by a heat treatment such as a reflow process and the gap space between the semiconductor chip 1200 and the upper surface of the circuit board 1100 may be filled up with an under-filling layer (not shown). Thus, the semiconductor chip 1200 may be electrically and mechanically bonded to the circuit board 1100 with high reliability due to the interconnectors 1210 and the under-filling layer.

Although not illustrated, the semiconductor chip 1200 may also be mounted on the circuit board 1100 in such a configuration that the active face may face upwards and thus the semiconductor chip 1200 may be bonded to the circuit board 1100 by a bonding wire.

The semiconductor chip 1200 may include, for example, a single chip structure and/or a multichip structure such as a chip stack package in which a plurality of the chips may be stacked. Particularly, the chips of the multichip structure may be electrically connected with each other by various connecting members such as penetration electrodes and bonding wires.

The single chip structure may include a memory device, for example, a dynamic random access memory (DRAM) device and a flash memory device and a logic device for driving the memory device. The single chip structure may include, for example, a chip scaled package (CSP) having a single semiconductor chip such as a wafer level chip scaled package (WLCSP) in which a plurality of semiconductor chips and solder bumps may be bonded on a single wafer and the assembly of the semiconductor chips and the solder bumps may be separated into pieces by a unit of the semiconductor chip or a die. The flip chip structure of the semiconductor chip 1200 may be introduced as the single chip structure in the present example embodiment.

The multichip structure may include a single package structure in which a plurality of memory chips or at least one memory chip and at least one logic chip may be stacked on a single circuit board. For example, the logic chip may include a wafer-level chip and the memory chip may include a sawed chip. Thus, a plurality of the sawed chips may be stacked on the wafer-level logic chip, thereby manufacturing the multichip structure. In some embodiments, the memory chip and the logic chip may be arranged on an upper surface and a lower surface of an interposer, respectively, thereby manufacturing a system in package (SIP) structure.

In the present example embodiment, the semiconductor chip 1200 may include a system on chip (SoC) structure in which a memory device 1250, an operation device, a logic device 1240 and a plurality of passive devices may be manufactured in a single chip. For example, the semiconductor chip 1200 may include a central process unit (CPU) 1220, a graphic process unit (GPU) 1230, a logic device 1240 connected with the CPU 1220 and the GPU 1230, and a memory device 1250, as illustrated in FIG. 5B. In such an embodiment, the semiconductor package 1900 may function as an application process (AP) for a mobile system.

The amount of heat generated from the CPU 1220 and the GPU 1230 may be much larger than that generated from the logic device 1240 and the memory device 1250 Thus, an overall amount of heat generated from the semiconductor chip 1200 may be mainly determined by the heat generated by the CPU 1220 and the GPU 1230. Particularly, when a high driving power is instantaneously applied to the semiconductor chip 1200, the temperatures of the CPU 1220 and the GPU 1230 may become higher than the reference temperatures, respectively, while the temperature of the rest of the semiconductor package 1200 not including the CPU 1220 and the GPU 1230 may be less than the reference temperature. For those reasons, the heat dissipation from the semiconductor chip 1200 may need to be focused to reduce the temperatures of the CPU 1220 and the GPU 1230.

For example, the encapsulant 1300 may be arranged on the circuit board 1100 in such a configuration that the semiconductor chip 1200 may be covered with the encapsulant 1300 and be protected from external surroundings. Further, the semiconductor chip 1200 may be stably fixed to the circuit board 1100 by the encapsulant 1300. The encapsulant 1300 may include a molding unit 1310 arranged on a whole surface of the circuit board 1100 to cover the semiconductor chip 1200 and having an insulating resin and an under-filling layer 1320 interposed between the circuit board 1100 and the semiconductor chip 1200 to thereby secure the semiconductor chip 1200 to the circuit board 1100.

The molding unit 1310 may include, for example, an epoxy resin, a thermosetting resin and/or a mixture thereof together with silicate, catalyst and various pigments. In the present example embodiment, the molding unit 1310 may include, for example, the epoxy resin such as an epoxy molding compound (EMC) and the under-filling layer 1320 may include, for example, a mixture of the epoxy resin and a curing agent. A dissipating pillar such as silica may be further included in the under-filing layer.

While the present example embodiment discloses that the semiconductor chip 1200 may be covered with the molding unit 1310, an upper surface of the molding unit 1310 may be coplanar with a surface of the semiconductor chip 1200 in such a way that the surface of the semiconductor chip 1200 may be exposed to the heat slug 1000. Particularly, when the semiconductor chip 1200 may be configured to have the face-down structure, the molding unit 1310 and a rear portion of the semiconductor chip 1200 may be planarized together with each other, until the upper surface of the molding unit 1310 and the rear surface of the semiconductor chip 1200 may be coplanar with each other, thereby reducing the thickness of the semiconductor chip 1200.

The heat slug 1000 may be arranged on the encapsulant 1300. The heat generated from the semiconductor chip 1200 may be dissipated outwards through the heat slug 1000. For example, an adhesive (not shown) having good thermal conductivity may be interposed between the encapsulant 1300 and the heat slug 1000, so that the heat slug 1000 may be adhered to the encapsulant 1300.

The thermal conductive adhesive may include, for example, insulating materials such as, for example, epoxy resin, polyimide and permanent photoresist. Particularly, a supplemental dissipating agent (not shown) may be included in the thermal conductive adhesive, and, thus, minute grooves and holes between the encapsulant 1300 and/or the semiconductor chip 1200 and the adhesive may be filled up with the supplemental dissipating agents. The supplemental dissipating agents may comprise thermal conductive materials and the heat dissipation from the semiconductor chip 1200 to the heat slug 1000 may be accelerated by the supplemental dissipating agents.

For example, the supplemental dissipating agent may include, for example, a thermal interface material (TIM) layer, a metal paste and nano-sized particles. Particularly, when electrical conductive materials are included in the thermal conductive adhesive and the thermal conductive adhesive is connected to an external grounding circuit, the noise characteristics and electromagnetic interference (EMI) characteristics of the semiconductor package 1900 may be improved by the electrical conductive materials.

The heat slug 1000 may include the thermoelectric element 300 of which the electrical characteristics may be interacted with heat generated from the semiconductor chip 1200. Thus, the heat generated from the semiconductor chip 1200 may be forcibly dissipated by the thermoelectric element 300 of the heat slug 1000 according to the detected temperature of the semiconductor chip 1200. That is, the heat slug 1000 may be operated at an active cooling mode and a passive cooling mode according to the detected temperature of the semiconductor chip 1200, as described above.

In the present example embodiment, the heat slug 1000 may have substantially the same structures as the heat slug 902 shown in FIG. 3A, except that a plurality of the thermoelectric elements 300 may be arranged on the heat slug 1000. The thermoelectric element 300 may include the thermistor 310 detecting the temperature of the semiconductor chip 1200 and the peltier effect device 320 conducting the heat transfer from the semiconductor chip 1200 to the body 100 of the heat slug 1000, so that the thermoelectric element 300 may function as an active heat transfer device.

As illustrated in FIG. 5B, the heat slug 1000 may include first and second thermoelectric members 300a and 300b and each thermoelectric element may have substantially the same structure as the thermoelectric element of the heat slug 902 illustrated in FIG. 3A. Thus, the first thermoelectric element 300a may include a first thermistor 310a and a first peltier device 320a and the second thermoelectric element 300b may include a second thermistor 310b and a second peltier device 320b.

In the present example embodiment, the first thermoelectric element 300a may make contact with the CPU 1220 and the second thermoelectric element 300b may make contact with the GPU 1230. Thus, the heat dissipated from the semiconductor chip 1200 is focused to reduce the temperature of the CPU 1220 and the GPU 1230.

The conductive pattern 400 may be arranged in such a way that the CPU 1220 and the GPU 1230 may be exposed through the conductive pattern 400, so that the first and the second thermoelectric elements 300a and 300b may be positioned on the CPU 1220 and the GPU 1230, respectively. The first and the second thermoelectric elements 300a and 300b may be electrically connected to the conductive pattern 400 by the bonding wires 410. The adhesion of the heat slug 1000 to the encapsulant 1300 may permit the first and the second thermoelectric elements 300a and 300b to be positioned on the CPU 1220 and the GPU 1230, respectively.

The conductive pattern 400 may be electrically connected to the inner circuit pattern 1120 of the circuit board 1100 through the contact members 500. Thus, the first and the second thermoelectric elements 300a and 300b may be electrically connected to the inner circuit pattern 1120 through the conductive pattern 400 and the contact members 500. The first thermistor 310a may detect the temperature of the CPU 1220 and the first peltier device 320a may actively transfer the heat generated from the CPU 1220 to the body 100 of the heat slug 1000 according to the detected temperature of the CPU 1220. In the same way, the second thermistor 310b may detect the temperature of the GPU 1230 and the second peltier device 320b may actively transfer the heat generated from the GPU 1230 to the body 100 of the heat slug 1000 according to the detected temperature of the GPU 1230.

A control unit 1241 may be arranged in the logic device 1240 that may be electrically connected to the first and the second thermoelectric elements 300a and 300b through the inner circuit pattern 1120. The control unit 1241 may individually and independently control the first and the second thermoelectric elements 300a and 300b. Thus, when the temperature of the CPU 1220 detected by the first thermistor 310a is higher than the preset reference temperature of the CPU 1220, the control unit 1241 may generate the dissipation signal for forcibly dissipating the heat from the CPU 1200. The dissipation signal may be transferred to the first peltier device 320a by the control unit 1241 through the conductive pattern 400. Thus, the first peltier effect device 320a may forcibly transfer the heat generated from the CPU 1220 to the body 100 of the heat slug 1000, thereby reducing the temperature of the CPU 1220 by an active cooling process performed by the first peltier effect device 320a. In the same way, when the temperature of the GPU 1230 detected by the second thermistor 310b is higher than the preset reference temperature of the GPU 1230, the control unit 1241 may generate the dissipation signal for forcibly dissipating the heat from the GPU 1230. The dissipation signal may be transferred to the second peltier effect device 320b by the control unit 1241 through the conductive pattern 400. Thus, the second peltier effect device 320b may forcibly transfer the heat generated from the GPU 1230 to the body 100 of the heat slug 1000, thereby reducing down the temperature of the GPU 1230 by an active cooling process performed by the second effect peltier device 320b.

When a high power is instantaneously applied to the semiconductor chip 1200, a larger amount of heat may be generated from the CPU 1220 and the GPU 12130 than the logic device 1240 and the memory device 1250. Thus, the temperatures of the CPU 1220 and the GPU 1230 may be instantaneously increased due to the large amount of the heat in the semiconductor package 1900.

The first and the second thermistors 310a and 310b may detect the temperatures of the CPU 1220 and the GPU 1230, respectively, in real-time or a preset period and may transfer the detected temperatures to the control unit 1241. When the detected temperatures of the CPU 1220 and the GPU 1230 are determined to be higher than the reference temperatures thereof, respectively, the control unit 1241 may generate the control signal to drive the first and/or the second effect peltier devices 320a and 320b. As a result, the heat may be forcibly transferred to the body 100 of the heat slug 1000 from the CPU 1220 and/or the GPU 1230 by the first and the second peltier effect devices 320a and 320b. Thereby, the temperatures of the CPU 1220 and/or GPU 1230 are reduced by an active cooling process. Particularly, the thermoelectric elements 300a and 300b may be individually and independently operated only when the detected temperatures of the CPU 1220 and the GPU 1230 are higher than the reference temperatures, respectively.

Accordingly, the active cooling process by the thermoelectric element 300, that is, thermoelectric elements 300a and 300b, may be locally performed at high-temperature sites of the semiconductor chip 1200 where a relatively larger amount of the heat may be generated among the whole semiconductor chip 1200, thereby increasing an overall efficiency of the heat dissipation of the heat slug 1000 with respect to the semiconductor chip 1200.

While the present example embodiment discloses a mobile AP including the CPU and the GPU from which a relatively large amount of the overall heat of the mobile AP may be generated (high heat generating elements) and the active cooling process may be individually and independently performed on the CPU 1220 and GPU 1230 by the first and the second thermoelectric elements 300a and 300b, respectively, three or more of the highly heat generating elements may be provided with the semiconductor chip 1200 and the thermoelectric elements 300 may be provided with every high heat generating element to thereby individually perform the active cooling process on each of the high heat generating elements of the semiconductor chip 1200.

In the present example embodiment, the thermoelectric element 300 may include the thermistor 310 and the peltier device 320 in the heat slug 1000 as shown in FIG. 3A. However, the thermoelectric element 300 may also include one of the thermistor and the peltier device as shown in FIGS. 1A and 2A.

According to the example embodiments of the semiconductor package of the present inventive concepts, a temperature detector such as the thermistor and a heat transfer unit such as the peltier device may be arranged not on the semiconductor chip but on the heat slug. The heat slug may be combined to the semiconductor chip and/or the encapsulant in such a way that the thermistor and the peltier device may be positioned on the semiconductor chip. Thus, although the space for the temperature detector and the heat transfer unit has been reduced as the recent semiconductor packages have been highly integrated with high performance, the temperature detector and the heat transfer unit may be sufficiently provided with the semiconductor package without the space margin limitations, since the temperature detector and the heat transfer unit may be arranged on the heat slug, not on the semiconductor chip. Thus, the efficiency of the heat dissipation in the semiconductor package is improved. When the semiconductor chip includes a plurality of heat sources, the temperature detector and the heat transfer unit may be individually and independently provided with every heat source. Thus, the heat dissipation may be individually and independently performed at each of the heat sources. In an embodiment in which the SoC structure in which a plurality of functional unit chips may be arranged in a single die and the amount of the heat from the each unit chip may be different from one another, the temperature detector and the heat transfer unit may be sufficiently provided at each unit chip without the space margin limitation since the temperature detector and the heat transfer unit may be provided on the heat slug, not on the unit chip of the SoC. Thus, the efficiency of the heat dissipation of the SoC is improved.

Particularly, when the thermistor and the peltier effect device are provided with the semiconductor package, the heat dissipation may be forcibly performed only when the detected temperature of the semiconductor chip is higher than the reference temperature. Thus, an active cooling process may be performed on the semiconductor chip only when the detected temperature of the semiconductor chip is higher than the reference temperature, while a passive cooling process may still be performed on the semiconductor chip when the detected temperature of the semiconductor chip is under the reference temperature. Accordingly, the efficiency of the heat dissipation of the semiconductor package may be remarkably increased.

In addition, the heat slug of the example embodiments of the present inventive concepts may increase an overall operation efficiency of the semiconductor package. According to the conventional thermal throttling controller of the semiconductor package, a plurality of the heat sources may be provided with the semiconductor chip and the driving power to the semiconductor chip may be automatically broken when the temperature of any one of the heat sources is higher than the reference temperature, which may have significantly decreased the operational efficiency of the semiconductor chip. However, according to the heat slug of the semiconductor package of the present inventive concepts, the active cooling process may be performed only on the high heat generating heat source(s) of the semiconductor chip, and, thus, the heat of the high heat generating heat source(s) may be dissipated outwards by the heat slug to the external surroundings. Therefore, the temperature of the heat source(s) may be controlled based on the reference temperatures while the driving power may be still applied to the semiconductor chip and the cut off of the driving power to the semiconductor chip may be minimized. Thus, the operation efficiency of the semiconductor package may be significantly increased.

FIG. 6 is a cross-sectional view illustrating a semiconductor package 2900 including the heat slug shown in FIG. 3A in accordance with another example embodiment of the present inventive concepts.

Referring to FIG. 6, the semiconductor package 2900 may include a circuit board 2100 having an inner electrical circuit pattern 2120 therein, and a semiconductor chip 2200 mounted on the circuit board 2100 and electrically connected with the inner circuit pattern 2120 of the circuit board 2100. The semiconductor package 2900 may include an encapsulant 2300 arranged on the circuit board 2100 in such a way that the semiconductor chip 2200 may be protected from surroundings and stably fixed to the circuit board 2100, and a heat slug 2000 positioned on the encapsulant 2300 and dissipating the heat generated from the semiconductor chip 2200 outwards to the external surroundings.

The circuit board 2100 and the semiconductor chip 2200 may be have substantially the same structures as the circuit board 1100 and the semiconductor chip 1200 illustrated in FIG. 5, and, thus, any further detailed descriptions on the circuit board 2100 and the semiconductor chip 2200 will be omitted hereinafter. The heat slug 2000 may have substantially the same structures as the heat slug 902a illustrated in FIG. 3B, and, thus, the any further detailed descriptions on the heat slug 2000 will be also omitted hereinafter. In FIG. 6, the same reference numerals of the heat slug 2000 denote the same elements of the heat slug 902a in FIG. 3B.

Particularly, since the heat slug 2000 may include the control chip 600 that may be connected with the thermistor 310 and the peltier effect device 320, no control unit is needed in the semiconductor chip 2200 for generating the control signals for driving the thermistor 310 and the peltier effect device 320. In addition, since the detected temperatures of the semiconductor chip 2200 and the control signal are not transferred to the control unit in the semiconductor chip 2200 in the embodiment including control unit 600, the contact members 500, which may connect the conductive pattern 400 of the heat slug 2000 with the inner circuit pattern 2120, may not necessarily comprise conductive materials. Thus, the active cooling process to the semiconductor chip 2200 may be performed only by the heat slug 2000, thereby decreasing an overall thickness of the semiconductor package 2900.

In the present example embodiment, the encapsulant 2300 include a molding unit 2310 arranged on a whole surface of the circuit board 2100 to fix the semiconductor chip 2200 and an under-filling layer 2320 interposed between the molding unit 2310 and the heat slug 2900. Thus, the heat slug 2000 is secured to the molding unit 2310 and a gap space between the molding unit 2310 and the heat slug 2000 is filled. Particularly, an upper surface of the molding unit 2310 may be coplanar with a surface of the semiconductor chip 2200, and thus the surface of the semiconductor chip 2200 may be exposed. In such a case, the thermistor 310 and the peltier device 320 may make contact with the surface of the semiconductor chip 2200, so that the heat slug 2000 may have an exposed molded under-filling (eMUF) structure.

The molding unit 2310 may configured in such a structure that the semiconductor chip 2200 may be exposed through the molding unit 2310 and the body 100 of the heat slug 2000 may be shaped into a plate without any bended portions. The thermistor 310 and the peltier device 320 arranged on a lower surface of the body 100 may make direct contact with the semiconductor chip 2200 and the gap spaces between the body 100 and the molding unit 2310 and between the body 100 and the semiconductor chip 2200 may be filled up with the under-filling layer 2320.

In an example embodiment, a supplemental coupling member 2400 may be further provided with the semiconductor package 2900. For example, the supplemental coupling member 2400 may penetrate through the encapsulant 2300 at the peripheral portion of the circuit board 2100, and thus the heat slug 2000 may be combined to the circuit board 2100 with higher mechanical reliability. For example, the encapsulant 2300 may be partially removed from the peripheral portion of the circuit board 2100 by a laser drill, thereby forming a plurality of openings at the peripheral portion of the circuit board 2100. Then, gap-fill materials having sufficient mechanical rigidity may be filled into the opening of the encapsulant 2300, thereby forming the supplemental coupling member 2400 at the peripheral portion of the circuit board 2100. Therefore, the heat slug 2000 and the circuit board 2100 may be sufficiently coupled to each other with high mechanical reliability even though no contact member is provided between the heat slug 2000 and the circuit board 2100.

According to the example embodiments of the heat slug and the semiconductor package including the same, at least one of the temperature detector such as the thermistor and the heat transfer unit such as the peltier device may be arranged on the heat slug in such a configuration that the temperature detector and the heat transfer unit may be positioned on or over the heat sources of the semiconductor chip. Thus, a forcible heat dissipation may be performed only on some of the heat sources when the temperatures of the heat sources are higher than the reference temperatures, respectively, by the thermoelectric elements of the heat slug. Thus, the cut off of the driving power to the semiconductor chip may be minimized even though some of the heat sources may temporarily have a high temperature over the reference temperature. Accordingly, the operation efficiency of the semiconductor chip having the plurality of heat sources may be sufficiently improved by the heat slug having the thermoelectric elements. In addition, the dissipation mode of the heat slug may be automatically changed between the active mode and the passive mode according to the temperature of the heat sources and the heat dissipation may be individually performed on each of the heat sources independently from one another. When the temperature of the heat source is lower than the reference temperature, the heat slug may transfer the heat outwards from the normal heat source in the passive mode. In contrast, when the temperature of the heat source is higher than the reference temperature due to an instantaneous excessive operation, the heat slug may forcibly transfer the heat outwards from the excessively operated heat source in the active mode by using the heat transfer unit such as the peltier device.

In the embodiment of the SoC structure in which a plurality of functional unit chips may be arranged in a single die and the amount of the heat from the each unit chip may be different from one another, the temperature detector and the heat transfer unit may be sufficiently provided at each unit chip without the space margin limitation, since the temperature detector and the heat transfer unit may be provided on the heat slug, not on the unit chip of the SoC. Thus, the efficiency of the heat dissipation of the SoC is improved. Thus, although the semiconductor package may be downsized and the number of the functional unit chips may increase in the semiconductor chip, the heat may be sufficiently dissipated from each of the unit chips through the active cooling process or the passive cooling process of the heat slug.

Particularly, when the thermistor and the peltier effect device are provided with the semiconductor package, the heat dissipation may be forcibly performed only when the detected temperature of the semiconductor chip is higher than the reference temperature. Thus, an active cooling process may be performed on the semiconductor chip only when the detected temperature of the semiconductor chip is higher than the reference temperature. In addition, a passive cooling process may still be performed on the semiconductor chip when the detected temperature of the semiconductor chip is under the reference temperature. Accordingly, the efficiency of the heat dissipation may be remarkably increased in the semiconductor package.

The present example embodiments of the semiconductor package may be applied to various electronic systems including semiconductor devices and IC chips such as telecommunication systems and storage systems. Particularly, in the embodiment of the mobile AP requiring high performance and high operation speed without the decrease of the operation efficiency, the active cooling member such as the thermistor and the peltier effect device may be arranged on the heat slug, not on the semiconductor chip of the mobile AP. Thus, a sufficient number of the active cooling members may be provided with the AP without any changes of the form factor of the AP.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A heat slug comprising:
a thermal conductive body having an active face and a dissipating face opposite to the active face;
a dielectric layer covering the active face of the thermal conductive body;
at least one thermoelectric element arranged on the dielectric layer, electrical characteristics of the thermoelectric element interacting with heat generated from a heat source; and
a conductive pattern arranged on the dielectric layer and electrically connected to the thermoelectric element.

2. The heat slug of claim 1, wherein the thermoelectric element comprises a thermistor for detecting a temperature of the heat source.

3. The heat slug of claim 1, wherein the thermoelectric element comprises a peltier effect device for forcibly transferring the heat to the thermal conductive body from the heat source by driving currents.

4. The heat slug of claim 1, wherein the thermoelectric element comprises a thermistor for detecting a temperature of the heat source and a peltier effect device for forcibly transferring the heat to the thermal conductive body from the heat source by driving currents, so that the thermoelectric element functions as an active thermoelectric heat transfer unit in which the peltier effect device is selectively operated according to the detected temperature of the heat source by the thermistor.

5. The heat slug of claim 1, further comprising at least one conductive contact member arranged at a peripheral portion of the thermal conductive body such that the conductive pattern is connected to an external body having the heat source through the conductive contact member.

6. The heat slug of claim 1, further comprising a control chip arranged on the dielectric layer and electrically connected with the conductive pattern and the thermoelectric element.

7. A semiconductor package comprising:
a circuit board having an inner electrical circuit pattern;
a semiconductor chip mounted on the circuit board and electrically connected with the inner circuit pattern of the circuit board;
an encapsulant arranged on the circuit board and encapsulating the semiconductor chip, thereby protecting the semiconductor chip from surroundings; and
a heat slug positioned on the encapsulant and dissipating a heat generated from the semiconductor chip outwards, the heat slug comprising a thermal conductive body having an active face and a dissipating face opposite to the active face, a dielectric layer covering the active face of the thermal conductive body, at least one thermoelectric element arranged on the dielectric layer having electrical characteristics interacting with the heat generated from the semiconductor chip and a conductive pattern arranged on the dielectric layer and electrically connected to the thermoelectric element.

8. The semiconductor package of claim 7, wherein the heat slug further comprises at least one conductive contact member arranged at a peripheral portion of the thermal conductive body in such a configuration that the conductive pattern is connected to an external body having the heat source through the contact member.

9. The semiconductor package of claim 8, wherein the thermoelectric element comprises at least one of a thermistor for detecting a temperature of the heat source and a peltier effect device for forcibly transferring the heat to the thermal conductive body from the heat source by driving currents.

10. The semiconductor package of claim 9, wherein the semiconductor chip comprises a control unit electrically connected to the thermoelectric element via the inner circuit pattern and the conductive contact member.

11. The semiconductor package of claim 10, wherein a reference temperature of the semiconductor chip is stored in the control unit and the control unit generates a control signal for driving the peltier effect device when a detected temperature of the semiconductor chip is higher than the reference temperature of the semiconductor chip.

12. The semiconductor package of claim 9, wherein the heat slug further comprises a control chip arranged on the dielectric layer and electrically connected with the conductive pattern and the thermoelectric element.

13. The semiconductor package of claim 12, wherein a reference temperature of the semiconductor chip is stored in the control chip and the control chip generates a control signal for driving the peltier effect device when a detected temperature of the semiconductor chip is higher than the reference temperature of the semiconductor chip.

14. The semiconductor package of claim 7, wherein the thermoelectric element comprises a thermistor for detecting a temperature of the heat source and a peltier effect device for forcibly transferring the heat to the thermal conductive body from the heat source by driving currents, and the heat slug further includes a control chip electrically connected with the conductive pattern and the thermoelectric element and in which a reference temperature of the semiconductor chip is stored, so that the control chip generates a control signal for driving the peltier effect device when the detected temperature of the semiconductor chip by the thermistor is higher than the reference temperature of the semiconductor chip.

15. The semiconductor package of claim 7, wherein a plurality of the thermoelectric elements are provided in the heat slug in such a configuration that the thermoelectric elements are arranged to correspond to local sites of the semiconductor chip, respectively, and the electrical characteristics of each of the thermoelectric elements are interacted with a heat generated from the corresponding local site independently from a rest of the local sites.

16. A semiconductor package comprising:
a semiconductor chip having at least one heat source;
a heat slug comprising:
a thermal conductive body having an active face and a dissipating face opposite to the active face;
a dielectric layer covering the active face of the thermal conductive body;
at least one thermoelectric element in contact with the at least one heat source, wherein the at least one thermoelectric element is configured detect a temperature of the heat source and dissipate heat to the thermal conductive body.

17. The semiconductor package of claim 16, wherein the at least one thermoelectric element comprises a thermistor for detecting a temperature of the heat source.

18. The semiconductor package of claim 16, wherein the at least one thermoelectric element comprises a peltier effect device for forcibly transferring the heat to the thermal conductive body from the heat source by driving currents.

19. The semiconductor package of claim 16, wherein the thermoelectric element comprises a thermistor for detecting a temperature of the heat source and a peltier effect device for forcibly transferring the heat to the thermal conductive body from the heat source by driving currents, so that the thermoelectric element functions as an active thermoelectric heat transfer unit in which the peltier effect device is selectively operated according to the detected temperature of the heat source by the thermistor.

20. The semiconductor package of claim 16, wherein the at least one heat source comprises a plurality of heat sources and the at least one thermoelectric element comprises a plurality of thermoelectric elements, and wherein the plurality of thermoelectric elements contact the plurality of heat sources, respectively.
